(19) United States
(12) Patent Application Publication
(10) Pub. No.: US 2005/0046349 A1
(43) Pub. Date: Mar. 3, 2005

(54) OLED display and production method thereof

(76) Inventors: Atsushi Tanaka, Yasu-gun (JP); Sayuri Kohara, Yasu-gun (JP); Koji Murayama, Yasu-gun (JP); Motohiko Asano, Yasu-gun (JP)

Correspondence Address: Karl F. Milde, Jr., Esq.;MILDE & HOFFBERG, L.L.P., Suite 460, 10 Bank Street, White Plains, NY, 10606, US

(21) Appl. No.: 10/926,260

(22) Filed: Aug. 25, 2004

(30) Foreign Application Priority Data
Aug. 27, 2003 (JP) 2003-209068

(51) Int. Cl. H01J 1/62

(52) U.S. Cl. 313/512; 313/504

(57) ABSTRACT

An OLED display 10 of the present invention comprises: a device substrate 12; an OLED device 14 formed on a surface of the device substrate 12; an encapsulation substrate 22 which is placed opposite to the device substrate 12 and through which light emitted from the OLED device 14 passes; a sealant 24 which is provided between a marginal area of the device substrate 12 and a marginal area of the encapsulation substrate 22 for encapsulating the OLED device 14; and an optically transparent desiccant layer 26 which is formed on a part of the encapsulation substrate 22 which is opposed to the OLED device 14.

### BACKGROUND OF THE INVENTION

1. Field of the Invention

The present invention relates to a top-emission OLED (organic light emitting diode) display and a production method thereof.

2. Description of Related Art

An LCD (liquid crystal display) and an OLED display are typical examples of a flat display. As shown in FIGS. 3(a) and 3(b), an OLED display 32a/32b has an OLED device 36a/36b on a device substrate 34a/34b, and has a structure that the OLED device 36a/36b is encapsulated by the device substrate 34a/34b, an encapsulation cap or an encapsulation substrate 44a/44b and a sealant 46a/46b so as to protect the OLED device 36a/36b from the ambient environment. A space is provided between the OLED device 36a/36b and the encapsulation cap, between the OLED device 36a/36b and the encapsulation substrate 44a/44b and between the OLED device 36a/36b and the sealant 46a/46b. The OLED device 36a/36b is composed of a bottom electrode 38a/38b, a top electrode 40a/40b, and an organic layer 42a/42b. The organic layer 42a/42b emits light.

There are two types of structures for the OLED display 32a/32b: a bottom-emission structure and a top-emission structure. In the bottom-emission OLED display 32a shown in FIG. 3(a), the device substrate 34a and the bottom electrode 38a are transparent, and light is emitted through the bottom electrode 38a and the device substrate 34a. In the top-emission OLED display 32b shown in FIG. 3(b), the encapsulation substrate 44b is transparent, and light is emitted through the encapsulation substrate 44b. Conventionally, the bottom-emission OLED display 32a has achieved more widespread use.

The OLED device 36a/36b is sensitive to moisture and oxygen. For this reason, a desiccant 48a/48b is provided inside the OLED display 32a/32b, and then the OLED device 36a/36b is encapsulated to protect it from the ambient environment. In the bottom-emission OLED display 32a, it is not necessary that light passes through the encapsulation cap 44a. The encapsulation cap 44a can be made of metallic material which is not optically transparent. A room for the desiccant 48a can be relatively easily prepared. The desiccant 48a is packed in a baglike container and bonded to the encapsulation cap 44a with adhesive. However, a special apparatus for bonding the desiccant 48a is needed before encapsulating the OLED device 36a, which causes an increase in cost in mass production.

In the bottom-emission OLED display 32a, various circuits (not shown) are formed on the device substrate 34a. Therefore, an aperture ratio of the OLED display 32a is reduced. On the contrary, in the case of the top-emission OLED display, the aperture ratio is enlarged, but the placement of the desiccant 48b causes a big problem. For example, a recessed part 50 is formed in the encapsulation substrate 44b and the desiccant 48b packed in a baglike container is bonded to the recessed part 50. However, an additional step of forming the recessed part 50 in the encapsulation substrate 44b is necessary, so that the production cost is increased.

As shown in FIG. 4, in the OLED display 33, a plurality of OLED devices 36b are separated by ribs 52, and the desiccant 48b has to be bonded only to non-display area on a marginal area of the encapsulation substrate 44b. Therefore, a frame area X₂ of the OLED display 33 becomes wider. However, in the case of a large-screen OLED display 33, it is not sufficient that the desiccant 48b is provided to the marginal area of the encapsulation substrate 44b, because the desiccant 48b cannot exert its effect on all the OLED devices 36b. The desiccant 48b can be fixed to the encapsulation substrate 44b with resin. However, it is difficult to form a resin film of even thickness, and the resin reduces the effect of the desiccant 48b.

A patent document 1 discloses an OLED display with a desiccant layer formed on an encapsulation substrate. In the embodiments of this patent document, it is described that a transparent bottom electrode, an OLED layer, and a ytterbium top electrode are disposed on a glass substrate in this order. This structure is a well-known bottom emission structure. A desiccant layer on a counter substrate is produced from a porous film, so that the surface area of the desiccant layer becomes large. The desiccant layer is produced by spin coating or dip coating desiccant material and then by forming it into porous film by the sol-gel process. The desiccant layer having a wide surface area can have equal hygroscopic property to fine-powdered desiccant. Since the desiccant material is formed into film, the desiccant layer causes less particle contamination than the fine-powdered desiccant material.

However, since the desiccant layer is porous film, it becomes clouded. If such clouded layer is applied to the top-emission OLED display, the clouded porous film is provided on a path of light, so that the OLED display cannot be used as a display unit. Further, the porous film causes a diffused reflection of light, so that straight light which is required by a display unit cannot pass through the porous film. Furthermore, since the desiccant layer is formed by spin coating or dip coating desiccant material, the desiccant layer does not have even thickness and the light passing through the layer is not uniform. Therefore, the desiccant layer disclosed in the patent document 1 cannot be applied to the top-emission OLED display, and it can be used only in the bottom-emission OLED display.

A patent document 2 discloses an OLED device in which a mixed layer of a desiccant and a silicon compound is provided on an encapsulation substrate. In this case, a mixture of a desiccant and a silicon compound is applied to the encapsulation substrate and then hardened. However, since the desiccant and the silicon compound differ in refractive index, light may reflect diffusely. Since the mixed layer is provided on the encapsulation substrate only by applying the mixture to the encapsulation substrate and then hardening it, the surface of the mixed layer is rough and the rough surface may cause light to reflect diffusely. FIG. 1 of the patent document 2 clearly shows that the mixed layer has a rough surface. Therefore, the OLED device of the patent document 2 is the one used in the bottom-emission OLED structure.

A patent document 3 discloses an OLED display in which an absorption layer prepared from a desiccant and a resin is formed on an encapsulation substrate. In this case, the absorption layer is formed by spreading a mixture of a desiccant and a resin evenly on an encapsulation substrate by means of a doctor blade and then self-cooling it. However, the absorption layer is a mixed layer of the desiccant and the resin, so that their different refractive indexes may cause light to reflect diffusely. The OLED display of the patent document 3 is a bottom-emission OLED display.

[Document 1] Japanese Unexamined Patent Publication No. (Patent Kokai No.) 2002-216951 (FIG. 1)

[Document 2] Japanese Unexamined Patent Publication No. (Patent Kokai No.) 2000-277254 (FIG. 1)

[Document 3] Japanese Unexamined Patent Publication No. (Patent Kokai No.) 2001-345175 (FIG. 1 and FIG. 2)

### SUMMARY OF THE INVENTION

An OLED display of the present invention comprises: a device substrate; an OLED device formed on a surface of the device substrate; an optically transparent encapsulation substrate which is placed opposite to the surface of the device substrate; a sealant which is provided between a marginal area of the device substrate and a marginal area of the encapsulation substrate which encapsulates the OLED device; and an optically transparent desiccant layer which is formed on a part of the encapsulation substrate through which light emitted from the OLED device passes. In the OLED display, the OLED device is encapsulated by the device substrate, the encapsulation substrate, and the sealant, and the optically transparent desiccant layer is formed on the encapsulation substrate through which the light emitted from the OLED device passes.

A method of producing an OLED display according to the present invention comprises: preparing a device substrate and an encapsulation substrate; forming an OLED device on a surface of the device substrate; forming an optically transparent desiccant layer on a part of the encapsulation substrate through which light emitted from the OLED device passes and which is opposed to the surface of the device substrate; and encapsulating the OLED device by placing the device substrate and the encapsulation substrate opposite to each other in such a manner that the OLED device on the device substrate is opposed to the desiccant layer on the encapsulation substrate and by providing a sealant between a marginal area of the device substrate and a marginal area of the encapsulation substrate.

### BRIEF DESCRIPTION OF THE DRAWINGS

FIG. 1 is a cross sectional view of an OLED display of the present invention.

FIG. 2 is a cross sectional view of an OLED display with a plurality of OLED devices.

FIG. 3(a) is a cross sectional view of a conventional bottom-emission OLED display and FIG. 3(b) is a cross sectional view of a conventional top-emission OLED display.

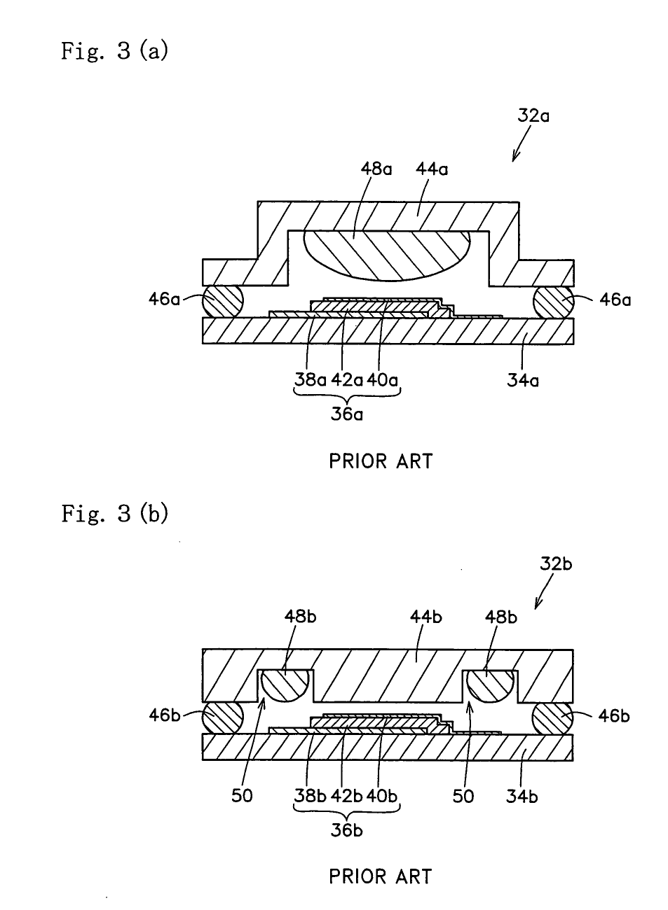

FIG. 4 is a cross sectional view of a top-emission OLED display with a plurality of OLED devices.

### DESCRIPTION OF THE PREFERRED EMBODIMENTS

Embodiments of the OLED display and the production method thereof according to the present invention will be described with reference to the drawings. The OLED display of the present invention is a top-emission OLED display.

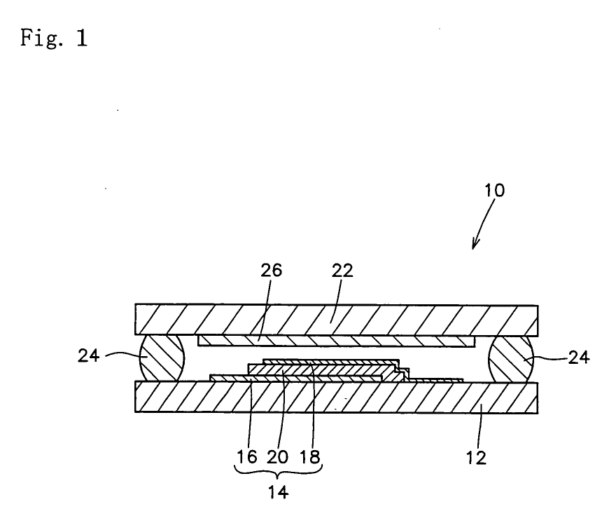

As shown in FIG. 1, an OLED display 10 of the present invention comprises: a device substrate 12; an OLED device 14 formed on a surface of the device substrate 12; an optically transparent encapsulation substrate 22 which is placed opposite to the surface of the device substrate 12 and through which light emitted from the OLED device 14 passes; a sealant 24 which is provided between an marginal area of the device substrate 12 and a marginal area of the encapsulation substrate 22 for encapsulating the OLED device 14; and an optically transparent desiccant layer 26 which is formed on a part of the encapsulation substrate 22 through which light emitted from the OLED device 14 passes.

Since the OLED display 10 of the present invention is a top-emission OLED display, the device substrate 12 may not necessarily be an optically transparent substrate. For example, the device substrate 12 may be made of plastic or glass. On the device substrate 12 are formed various circuits (not shown), on the circuits is formed a resin layer (not shown) for example, and on the resin layer is formed the OLED device 14. It is noted that various circuits and resin layer are omitted from FIG. 1 and the explanation of FIG. 1.

As a basic structure of the OLED device 14, the organic layer 20 is sandwiched between the bottom electrode 16 and the top electrode 18. In general, the bottom electrode 16 formed on the device substrate 12 is an anode. As the top electrode 18, a transparent or translucent electrode is used. In many cases, the organic layer 20 is composed of a plurality of layers such as a hole injection layer, a hole transport layer, a light emission layer, an electron transport layer, and electron injection layer.

The encapsulation substrate 22 is a transparent substrate such as glass. The light emitted from the OLED device 14 passes through the encapsulation substrate 22. A recessed part for putting the desiccant therein is not formed in the encapsulation substrate 22. Since the encapsulation substrate is not additionally processed for the purpose of bonding the desiccant thereto, it is easy to bond the desiccant to the encapsulation substrate. The device substrate 12 and the encapsulation substrate 22 are placed opposite to each other in such a manner that the OLED device 14 on the device substrate 12 are opposed to the desiccant layer 26 on the encapsulation layer 22, and the device substrate 12 and the encapsulation substrate 22 are connected by the sealant 24. Thus, the OLED device 14 can be encapsulated to protect it from the ambient environment.

The desiccant layer 26 is formed from alkali metal oxide or alkali earth metal oxide. A thickness of the desiccant layer 26 is made uniform and the desiccant layer is made homogeneous so that the light can pass through the layer 26 without reflecting diffusely. The desiccant layer 26 is not formed by any one of the coating methods disclosed in the patent documents 1 to 3 or by a dip-coating method, but is formed by deposition in a vacuum or under a reduced pressure.

For example, the desiccant layer 26 is made of CaO (calcium oxide) or BaO (barium oxide). The desiccant layer 26 is not formed from a mixture of a resin and desiccant, but is made from a single material like CaO or BaO. When the thickness of the desiccant layer 26 is about 200 nm, 90% or more of visible light can pass through the desiccant layer 26. Therefore, even if the desiccant layer 26 is formed on a part of the encapsulation substrate 22 through which light passes, the OLED display of the present invention can be used as a display unit without problems.

Next, a method of producing the OLED display 10 will be described.

(1) The device substrate 12 and the encapsulation substrate 22 are prepared. As the encapsulation substrate 22, an optically transparent substrate like a glass substrate is prepared.

(2) On the device substrate 12, the OLED device 14 is formed. For example, the aforementioned layers that make up the OLED device 14 are formed by a known vacuum deposition method.

(3) The optically transparent desiccant layer 26 is formed on the encapsulation substrate 22 including a part through which the light emitted from the OLED device 14 passes and which is opposed to a surface of the device substrate 12 on which the OLED device 14 is formed. The desiccant layer 26 is formed by (A) depositing alkali metal or alkali earth metal on the encapsulation substrate 22 to form an alkali metal layer or an alkali earth metal layer and (B) oxidizing the alkali metal layer or the alkali earth metal layer. In the step (A), the alkali metal layer or the alkali earth metal layer is formed by depositing Ca or Ba by a vacuum deposition method or by a sputtering deposition method. In the step (B), CaO or BaO is formed. The desiccant layer 26 of a desired thickness may be formed by repeatedly performing the step (A) and the step (B).

Examples of the oxidizing step (B) include a step of exposing the alkali metal layer or the alkali earth metal layer to air. When the alkali metal layer or the alkali earth metal layer is exposed to air for oxidization, it absorbs moisture from the air. Therefore, it is necessary to evaporate the moisture. In order to evaporate the moisture, the oxidized alkali metal layer or the oxidized alkali earth metal layer is heated in a vacuum or in an inert gas. As an inert gas, nitrogen gas or argon gas is used.

(4) The device substrate 12 and the encapsulation substrate 22 are placed opposite to each other in such a manner that the OLED device 14 on the device substrate 12 is opposed to the desiccant layer 26 on the encapsulation substrate 22, and the sealant 24 is provided between a marginal part of the device substrate 12 and a marginal part of the encapsulation substrate 22 so as to encapsulate the desiccant layer 26. Encapsulating of the desiccant layer 26 is performed in a vacuum or in an inert gas. As an inert gas, nitrogen gas or argon gas is used. The reason why the desiccant layer 26 is encapsulated in an inert gas is because oxygen and moisture that deteriorate the OLED device 14 are prevented from getting into the OLED display 10 during the encapsulation process.

In this way, the OLED display 10 is produced as described above. The desiccant layer 26 is formed by depositing alkali metal or alkali earth metal on the encapsulation substrate 22 by a vacuum deposition method or a sputtering deposition method. Therefore, unlike the layer formed by a spin coating method or a dip coating method as described in the patent document 1, the desiccant layer 26 of the present invention has a constant and uniform thickness and the light passing through the desiccant layer 26 does not reflect diffusely. It is difficult to form the desiccant layer by directly depositing alkali metal oxide or alkali earth metal oxide. However, in the present invention, alkali metal or alkali earth metal is deposited to form an alkali metal layer or an alkali earth metal layer and then oxidized, so that it is easy to form the desiccant layer. Further, unlike the desiccant layer described in the patent document 2 or 3, the desiccant layer of the present invention is not a mixed layer of a resin and a desiccant, so that light does not reflect diffusely due to differences in refractive index.

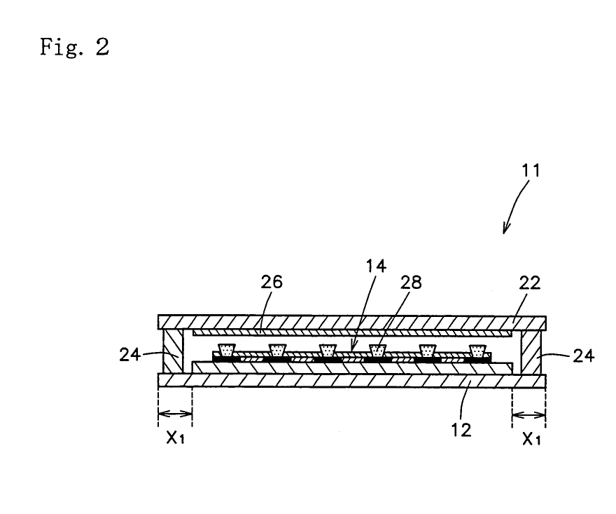

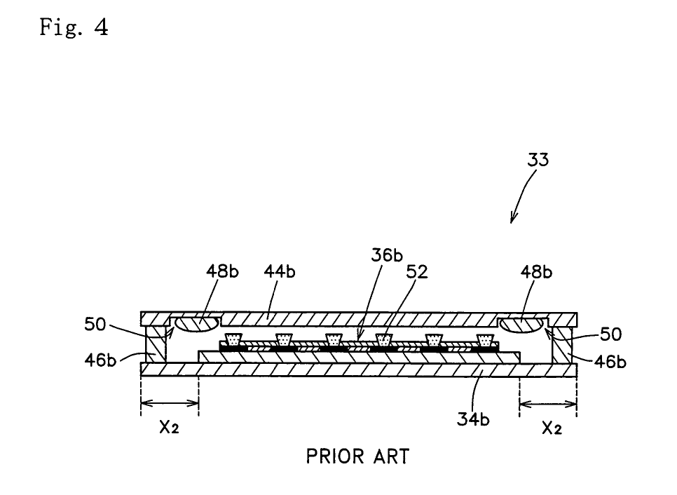

The aforementioned explanation can also be applied to the case where a plurality of OLED devices 14 are formed on the device substrate 12. As shown in FIG. 2, a plurality of OLED devices 14 are separated by ribs 28, and the desiccant layer 26 is formed over the whole surface of the encapsulation substrate 22. Compared to the desiccant 48b shown in FIG. 4 as prior art, the desiccant layer 26 can exert its effect evenly on all the OLED devices 14. Further, the desiccant is not bonded to the marginal area of the encapsulation substrate, so that a frame area X₁ is narrower than the frame area X₂ shown in FIG. 4. Thus the OLED display 11 can be effectively downsized.

While the embodiments of the present invention have thus been described with reference to the drawings, it should be understood that the present invention be not limited to the embodiments shown in the drawings. Various changes, modifications, and imnprovements can be made to the embodiments on the basis of knowledge of those skilled in the art without departing from the scope of the present invention. This application claims priority from Japanese Patent Application No. 2003-209068, which is incorporated herein by reference.

1. An OLED display comprising:
a device substrate;
an OLED device formed on a surface of the device substrate;
an optically transparent encapsulation substrate placed opposite to the surface of the device substrate;
a sealant which encapsulates the OLED device, said sealant provided between a marginal area of the device substrate and a marginal area of the encapsulation substrate; and
an optically transparent desiccant layer on at least a part of the encapsulation substrate through which light emitted from the OLED device passes.

2. The OLED display according to claim 1, wherein said desiccant layer is formed from alkali metal oxide or alkali earth metal oxide.

3. A method of producing an OLED display, comprising:
preparing a device substrate and an encapsulation substrate;
forming an OLED device on a surface of the device substrate;
forming an optically transparent desiccant layer on a part of the encapsulation substrate through which light emitted from the OLED device passes, said part of the encapsulation substrate opposed to the surface of the device substrate; and
encapsulating the OLED device by placing the device substrate and the encapsulation substrate opposite to each other in such a manner that the OLED device on the device substrate is opposed to the desiccant layer on the encapsulation substrate and by providing a sealant between a marginal area of the device substrate and a marginal area of the encapsulation substrate.

4. The method of producing an OLED display according to claim 3, wherein said step of forming an optically transparent desiccant layer comprises:
depositing alkali metal or alkali earth metal on the encapsulation substrate to form an alkali metal layer or an alkali earth metal layer; and
oxidizing the alkali metal layer or the alkali earth metal layer.

5. The method of producing an OLED display according to claim 4, wherein said oxidizing step comprises:
exposing the alkali metal layer or the alkali earth metal layer to air; and
after said exposing step, heating the oxidized alkali metal layer or the oxidized alkali earth metal layer in a vacuum or in an inert gas.

6. The method of producing an OLED display according to claim 4, wherein said encapsulating step is performed in a vacuum or in an inert gas.

7. The method of producing an OLED display according to claim 4, wherein said depositing step is performed using a vacuum deposition method or a sputtering deposition method.

8. The method of producing an OLED display according to claim 7, wherein said encapsulating step is performed in a vacuum or in an inert gas.
